(19) United States
(12) Patent Application Publication
(10) Pub. No.: US 2013/0200400 A1
(43) Pub. Date: Aug. 8, 2013

(54) PCB HAVING INDIVIDUAL REFLECTIVE STRUCTURE AND METHOD FOR MANUFACTURING LIGHT EMITTING DIODE PACKAGE USING THE SAME

(71) Applicant: Jong-Jin JANG, Suwon-si (KR)

(72) Inventor: Jong-Jin JANG, Suwon-si (KR)

(73) Assignees: DOOSUNG ADVANCED TECHNOLOGY CO., LTD., Suwon-si (KR); Jong-Jin Jang, Suwon-si (KR)

(21) Appl. No.: 13/559,924

(22) Filed: Jul. 27, 2012

(30) Foreign Application Priority Data
Feb. 6, 2012 (KR) 10-2012-0011927

(51) Int. Cl. H01L 33/08; H01L 33/60

(52) U.S. Cl. 257/88; 438/27; 257/E33.072

(57) ABSTRACT

A printed circuit board (PCB) having an individual reflective structure and a method for manufacturing a light emitting diode (LED) package using the same, which can prevent reabsorption of light between LED chips by providing an individual reflective structure between the LED chips when the LED package is configured using two or more LED chips. The PCB includes a PCB; a wiring pattern-forming material layer formed on the PCB with an insulating layer interposed therebetween; dams formed on the wiring pattern-forming layer around chip mounting areas of the PCB; and a light reabsorption prevention dam formed on the wiring pattern-forming material layer between the chip mounting areas where LED chips are mounted.

### CROSS-REFERENCE TO RELATED PATENT APPLICATION

This application claims the benefit of Korean Patent Application No. 10-2012-0011927, filed on Feb. 6, 2012, it the Korean Intellectual Property Office, the disclosure of which is incorporated herein in its entirety by reference.

### BACKGROUND OF THE INVENTION

1. Field of the Invention

The present invention relates to a light emitting diode (LED) package and, more particularly, to a printed circuit board (PCB) having an individual reflective structure and a method for manufacturing an LED package using the same, which can prevent reabsorption of light between LED chips by providing an individual reflective structure between the LED chips when the LED package is configured using two or more LED chips.

2. Description of the Related Art

A light emitting diode is an electronic device that produces minority carriers (electrons or holes) injected using p-n junctions in semiconductors and emits light by recombination of the minority carriers.

The light emitting diode has been used in various fields and has recently attracted much attention as a replacement for fluorescent lamps since its lifespan is semi-permanent and it has no toxic substances regulated by environmental regulations (such as RoHS, ELV, PFOS, etc.).

Typically, a light emitting diode chip is packaged in such a manner that the light emitting diode chip is bonded on a lead frame with Ag, for example, an N-type pad and a P-type pad of the light emitting diode chip are wire-bonded thereto, and then the resulting chip is sealed by epoxy molding.

The light emitting diode package configured in the above manner is mounted on a heat-dissipating plate for heat dissipation and then installed on a PCB, or otherwise mounted on a PCB by surface mount technology (SMT), for example, and then attached on a heat-dissipating plate.

Moreover, a light emitting diode array unit used in an LCD backlight, etc. for example, is manufactured by arranging a plurality of light emitting diode packages configured in the above manner on a PCB in the form of an array by surface mount technology (SMT), for example.

The light emitting diode array unit configured in the above manner is attached on a heat-dissipating plate for heat dissipation.

As such, conventionally, in order to manufacture the light emitting diode unit, it is necessary to employ a plurality of manufacturing processes having different characteristics such as a process of manufacturing the lead frame, a process of manufacturing the heat-dissipating plate, a process of manufacturing the light emitting diode package, a process of manufacturing the PCB, a process of mounting the light emitting diode package, etc.

That is, the light emitting diode cannot be exclusively manufactured by a single manufacturer but can be manufactured through the cooperation of other manufacturers. Thus, the manufacturing process of the light emitting diode unit is complicated and the manufacturing costs of the light emitting diode unit are increased, which is problematic.

Moreover, conventionally, the light emitting diode chip is mounted on the lead frame and packaged, and the light emitting diode package is mounted on the PCB. Thus, the overall thickness of the light emitting diode unit is increased, which is an obstacle to thinning of an electronic product employing the light emitting diode unit.

In particular, conventionally, for the heat dissipation of the light emitting diode, the light emitting diode chip is mounted on the lead frame and packaged, and then the light emitting diode package is installed on the PCB with the heat-dissipating plate interposed therebetween, or otherwise the light emitting diode package is mounted on the PCB and then connected to the heat-dissipating plate.

As a result, the overall thickness of the light emitting diode unit is increased, which is an obstacle to thinning of an electronic product employing the light emitting diode unit.

The light emitting diode unit of the prior art has limitations in improving the wavelength conversion efficiency of emitted light, and thus it is difficult to increase the light output, brightness, or color rendering.

To solve these problems, a structure in which a reflective groove having a reflective surface is formed in a chip mounting area of a heat-dissipating substrate and a light emitting diode is mounted thereon has been proposed.

However, according to this type of light emitting diode package, when two or more light emitting diode chips are mounted in the reflective groove, the light output may be reduced due to reabsorption of light between adjacent light emitting diode chips.

FIG. 1 shows the reduction in light output due to reabsorption of light between light emitting diode chips of a chip-on-board (COB) & chip-on-heat-sink (COH) type light emitting diode package, and FIG. 2 shows the reduction in light output due to reabsorption of light between light emitting diode chips of a chip-on-metal (COM) type light emitting diode package.

In detail, FIG. 1 shows the structure of a chip-on-board (COB) & chip-on-heat-sink (COH) type light emitting diode package, in which a PCB 10 such as an FR4 PCB (COB type PCB) or a metal PCB (COH type PCB) comprising an insulating layer 11 of 50 to 100 μm in thickness and a copper (Cu) layer 12 of ½ ounce (about 17 μm) or 1 ounce (about 34 μm) in thickness is used.

Here, it is necessary to form a silver (Ag) layer for wire bonding as a plating layer for LED packaging by COB & COH. However, it is impossible to directly plate the Cu layer with silver, and thus a nickel (Ni) layer is formed on the Cu layer by plating as a buffer layer for Ag plating.

Wiring pattern-forming material layers 12, 13 and 14 are formed by the above-described process, dams 16 each having a predetermined height to prevent a fluorescent material or silicone from spreading during application are formed, and then LED chips 15a and 15b are mounted thereon.

However, in this structure, the light output may be reduced due to reabsorption of light between the LED chip 15a and the adjacent LED chip 15b.

FIG. 2 shows the structure of a chip-on-metal (COM) type light emitting diode package, in which LED chips are mounted directly on a metal plate (or surface-treated metal plate) 20. In detail, LED chips 25a, 25b, 25c, 25d and 25e are mounted directly on the surface of the metal plate 20, electrical wiring layers 22, 23 and 24 are formed by a PCB manufacturing process and a Ni and Ag plating process, and then the metal plate 20 and a PCB manufactured by the above-described process are bonded by hot press, thus manufacturing a COM type metal PCB.

The wiring layers of the COM type metal PCB are formed on the PCB by forming first, second, and third wiring pattern-forming material layers 22, 23 and 24 using materials having excellent electrical conductivity such as Cu, Ni and Ag, dams 26 each having a predetermined height to prevent a fluorescent material or silicone from spreading during application are formed, and then LED chips 25a, 25b, 25c, 25d and 25e are mounted on the surface of the metal plate 20.

However, in this structure, the light output may also be reduced due to reabsorption of light between the LED chips 25a, 25b, 25c, 25d and 25e.

### SUMMARY OF THE INVENTION

The present invention has been made in an effort to solve the above-described problems associated with prior art, and an object of the present invention is to provide a PCB having an individual reflective structure and a method for manufacturing an LED package using the same, which can prevent reabsorption of light between LED chips by providing an individual reflective structure between the LED chips when the LED package is configured using two or more LED chips.

Another object of the present invention is to provide a PCB having an individual reflective structure and a method for manufacturing an LED package using the same, which can prevent reabsorption of light between LED chips by providing a dam structure for individual reflection by repeatedly printing white ink, by applying and curing a dam-forming material using a dispenser, or by directly forming a reflective structure between the LED chips when the LED package is configured using two or more LED chips, thus improving light efficiency.

Still another object of the present invention is to provide a PCB having an individual reflective structure and a method for manufacturing an LED package using the same, which can prevent reabsorption of light between LED chips by processing and manufacturing a PCB circuit by a chip-on-board (COB) & chip-on-heat-sink (COH) process or a chip-on-metal (COM) process and providing a dam structure for individual reflection between LED chips by printing, thus facilitating the process.

Yet another object of the present invention is to provide a PCB having an individual reflective structure and a method for manufacturing an LED package using the same, in which a process of providing a structure for individual reflection between LED chips is performed by printing using white ink, by applying and curing a dam-forming material, or by directly forming a reflective structure, which is suitable for the package structure and process, thus improving the efficiency of the process.

The objects of the present invention are not limited to the above-mentioned objects, and other objects that are not mentioned will be clearly understood by those skilled in the art from the following description.

According to an aspect of the present invention to achieve the above object of the present invention, there is provided a printed circuit board (PCB) having an individual reflective structure, the PCB comprising: a PCB; a wiring pattern-forming material layer formed on the PCB with an insulating layer interposed therebetween; a dam formed on the wiring pattern-forming layer around chip mounting areas of the PCB; and a light reabsorption prevention dam formed on the wiring pattern-forming material layer between the chip mounting areas where light emitting diode (LED) chips are mounted.

The PCB may have a structure in which two or more LED chips are mounted by a chip-on-board (COB) or chip-on-heat-sink (COH) process.

According to another aspect of the present invention to achieve the above object of the present invention, there is provided a PCB having an individual reflective structure, the PCB comprising: a metal plate; a wiring pattern stacked on the metal plate; dams formed on the wiring pattern around chip mounting areas of the metal plate; and light reabsorption prevention dams formed on the surface of the metal plate between the chip mounting areas where LED chips are mounted.

The metal plate may have reflection and gloss properties improved by surface treatment.

The surface treatment of the metal plate may improve the reflection and gloss properties by performing any one of coating, deposition, lamination, and sputtering on an aluminum plate.

The PCB may have a structure in which a plurality of LED chips are mounted in a single LED package by a chip-on-heat-sink (COH) process.

The light reabsorption prevention dam may be formed by repeatedly printing white ink, by applying and curing a dam-forming material, or by directly forming a reflective structure.

According to still another aspect of the present invention to achieve the above object of the present invention, there is provided a method for manufacturing an LED package using a PCB having an individual reflective structure, the method comprising: forming a wiring pattern-forming material layer on a metal plate with an insulating layer interposed therebetween; forming dams on the wiring pattern-forming layer around chip mounting areas of the metal plate and light reabsorption prevention dams on the wiring pattern-forming material layer between the chip mounting areas where LED chips are mounted, respectively; and bonding the LED chips to the chip mounting areas between which the light reabsorption prevention dams are formed and performing a wire bonding process for electrically connecting electrodes of the LED chips to bonding pads.

The forming of the dams and the light reabsorption prevention dams may be performed by repeatedly printing white ink, by applying and curing a dam-forming material using a dispenser, or by directly forming a reflective structure.

According to yet another aspect of the present invention to achieve the above object of the present invention, there is provided a method for manufacturing an LED package using a PCB having an individual reflective structure, the method comprising: forming light reabsorption prevention dams on a metal plate by repeatedly printing white ink on the surface of a metal plate between chip bonding areas where LED chips are mounted; forming a wiring pattern layer on a PCB and forming dams on the wiring pattern layer around the chip bonding areas by repeatedly printing white ink on the surface of the PCB; stacking the PCB having the wiring pattern layer and the dams on the metal plate having the light reabsorption prevention dams; and bonding the LED chips to the chip mounting areas between which the light reabsorption prevention dams are formed and performing a wire bonding process for electrically connecting electrodes of the LED chips to bonding pads.

According to still yet another aspect of the present invention to achieve the above object of the present invention, there is provided a method for manufacturing an LED package using a PCB having an individual reflective structure, the method comprising: forming a wiring pattern layer on a PCB and forming dams on the wiring pattern layer around chip bonding areas by repeatedly printing white ink on the surface of the PCB; stacking the PCB having the wiring pattern layer and the dams on a metal plate; forming light reabsorption prevention dams on the metal plate where LED chips are mounted by applying and curing a dam-forming material using a dispenser on the surface of the metal plate; and bonding the LED chips to the chip mounting areas between which the light reabsorption prevention dams are formed and performing a wire bonding process for electrically connecting electrodes of the LED chips to bonding pads.

According to a further aspect of the present invention to achieve the above object of the present invention, there is provided a method for manufacturing an LED package using a PCB having an individual reflective structure, the method comprising: forming a wiring pattern layer on a PCB and stacking the PCB having the wiring pattern layer on a metal plate; forming dams on the wiring pattern layer around chip mounting areas and light reabsorption prevention dams on the surface of the metal plate by applying and curing a dam-forming material using a dispenser on the surface of the metal plate where LED chips are mounted and on the top surface of the PCB; and bonding the LED chips to the chip mounting areas between which the light reabsorption prevention dams are formed and performing a wire bonding process for electrically connecting electrodes of the LED chips to bonding pads.

The forming of the dams on the wiring pattern layer and the light reabsorption prevention dams on the surface of the metal plate may be performed by directly forming a reflective structure in the dam-forming area, respectively.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram showing the configuration of a chip-on-board (COB) & chip-on-heat-sink (COH) type light emitting diode package;

FIG. 2 is a schematic diagram showing the configuration of a chip-on-metal (COM) type light emitting diode package;

FIG. 3 is a schematic diagram showing the configuration of a chip-on-board (COB) & chip-on-heat-sink (COH) type light emitting diode package in accordance with an exemplary embodiment of the present invention;

FIG. 4 is a schematic diagram showing the configuration of a chip-on-metal (COM) type light emitting diode package in accordance with another exemplary embodiment of the present invention;

FIGS. 5A and 5B are a plan view showing the configuration of a chip-on-board (COB) & chip-on-heat-sink (COH) type light emitting diode package and a flowchart showing a process of manufacturing the same in accordance with an exemplary embodiment of the present invention; and

FIGS. 6A and 6E are a plan view showing the configuration of a chip-on-metal (COM) type light emitting diode package and flowcharts showing processes of manufacturing the same in accordance with other exemplary embodiments of the present invention.

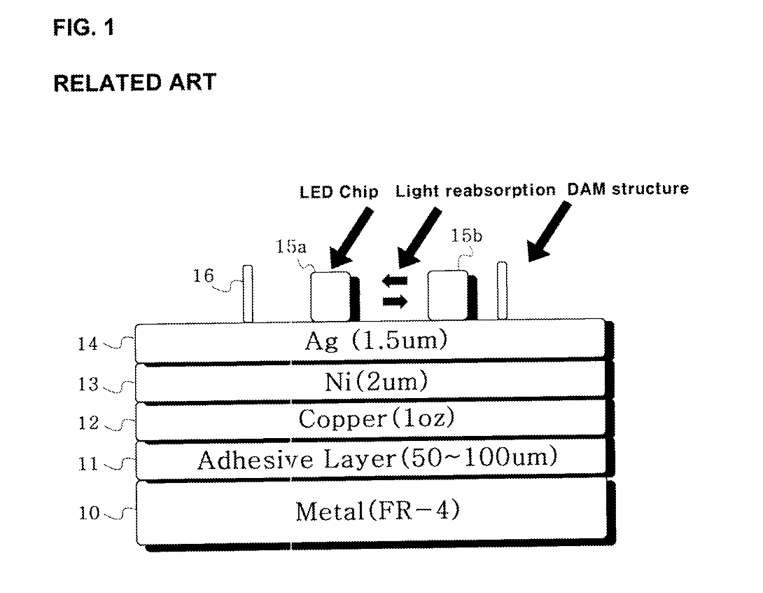

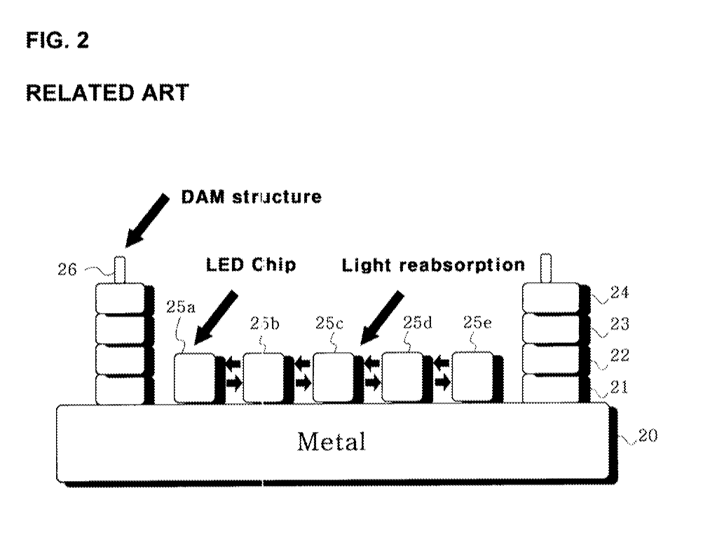

### DETAILED DESCRIPTION OF THE INVENTION

Hereinafter, preferred embodiments of a PCB having an individual reflective structure and a method for manufacturing an LED package using the same according to the present invention will be described in detail with reference to the accompanying drawings.

Features and advantages of the PCB having an individual reflective structure and the method for manufacturing an LED package using the same according to the present invention will be apparent from the following detailed description of the preferred embodiment of the present invention.

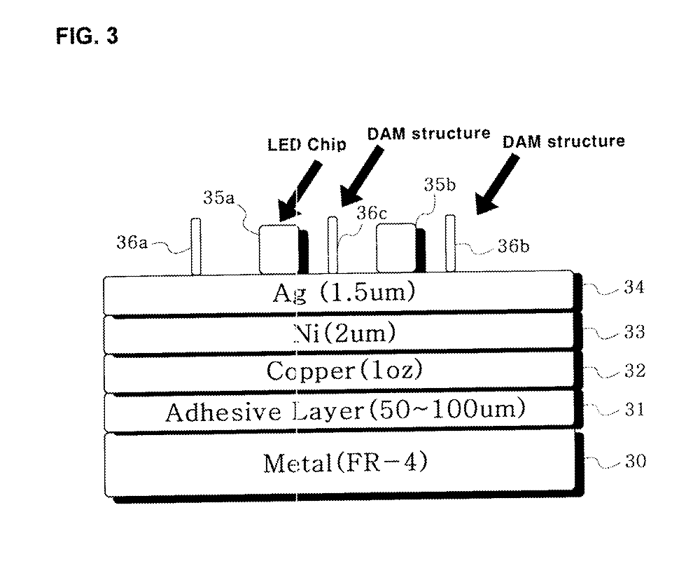

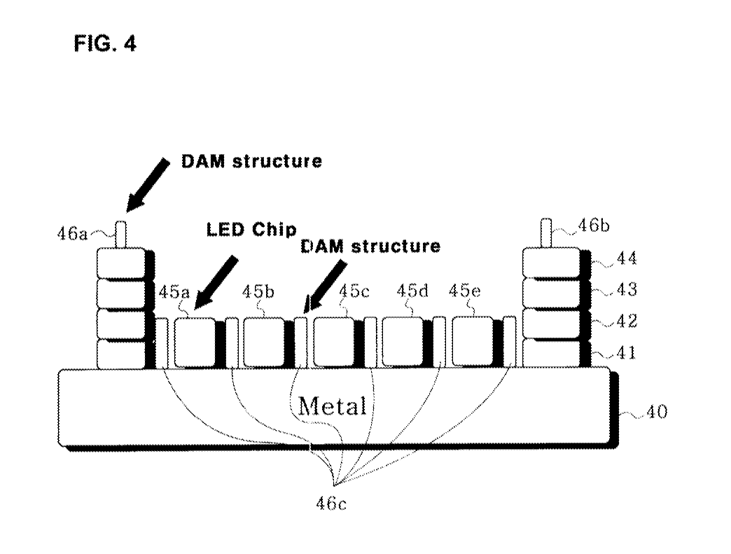

FIG. 3 is a schematic diagram showing the configuration of a chip-on-board (COB) & chip-on-heat-sink (COH) type light emitting diode package in accordance with an exemplary embodiment of the present invention, and FIG. 4 is a schematic diagram showing the configuration of a chip-on-metal (COM) type light emitting diode package in accordance with another exemplary embodiment of the present invention.

The present invention provides a PCB having an individual reflective structure and a method for manufacturing an LED package using the same, which can prevent reabsorption of light between LED chips by providing an individual reflective structure between the LED chips when the LED package is configured using two or more LED chips, thus improving light efficiency.

In the following description, a metal plate means the use of a metal plate with improved reflection and gloss properties through surface treatment, and the surface treatment of the metal plate improves the reflection and gloss properties by performing any one of coating, deposition, lamination, and sputtering on an aluminum plate.

As shown in FIG. 3, a chip-on-board (COB) & chip-on-heat-sink (COH) type light emitting diode package in accordance with an exemplary embodiment of the present invention uses a PCB 30 such as an FR4 PCB (COB type PCB) or a metal PCB (COH type PCB) comprising an insulating layer 31 of 50 to 100 μm in thickness and a copper (Cu) layer 32 of ½ ounce (about 17 μm) or 1 ounce (about 34 μm) in thickness.

That is, first, second, and third wiring pattern-forming material layers 32, 33 and 34 are formed of materials having excellent electrical conductivity such as Cu, Ni and Ag on the insulating layer 31 of 50 to 100 μm in thickness, dams 36a and 36b each having a predetermined height to prevent a fluorescent material or silicone from spreading during application are formed around chip mounting areas, a light reabsorption prevention dam 36c is formed between the chip mounting areas, and then LED chips 35a and 35b are mounted in the chip mounting areas.

Here, the light reabsorption prevention dam 36c may be formed by repeatedly printing white ink, by applying and curing a dam-forming material, or by directly forming a reflective structure.

In this structure, the light reabsorption prevention dam 36c is formed between the LED chip 35a and the adjacent LED chip 35b to prevent reabsorption of light between the LED chips 35a and 35b, thus improving light efficiency.

As shown in FIG. 4, a chip-on-metal (COM) type light emitting diode package in accordance with another exemplary embodiment of the present invention comprises a metal plate (or surface-treated metal plate) 40, wiring patterns 42, 43 and 44 stacked on the metal plate, dams 46a and 46b each having a predetermined height to prevent a fluorescent material or silicone from spreading during application and formed on the wiring patterns 42, 43 and 44 around chip mounting areas of the metal plate 40, and light reabsorption prevention dams 46c formed on the surface of the metal plate 40 between the chip mounting areas where LED chips 45a, 45b, 45c, 45d and 45e are mounted.

In this structure, the light reabsorption prevention dams 46c are formed between the LED chips 45a, 45b, 45c, 45d and 45e to prevent reabsorption of light between the LED chips 45a, 45b, 45c, 45d and 45e, thus improving light efficiency.

Here, the light reabsorption prevention dams 46c may be formed by repeatedly printing white ink, by applying and curing a dam-forming material, or by directly forming a reflective structure.

A method for manufacturing an LED package using the above-described PCB having the individual reflective structure will now be described

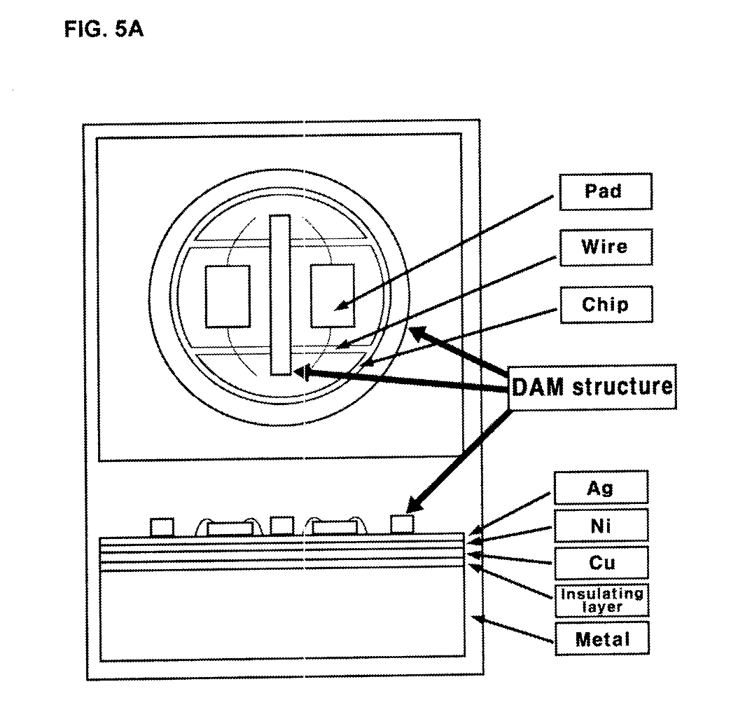

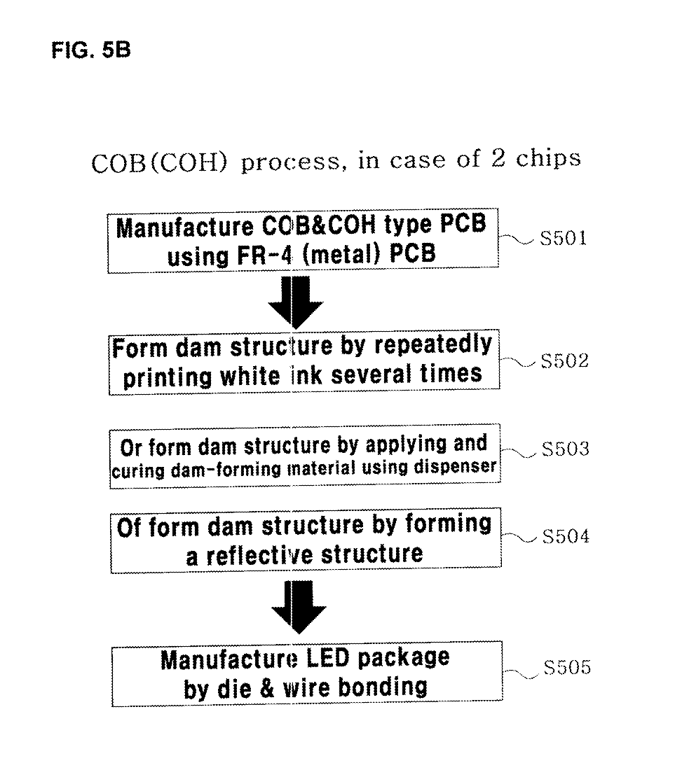

FIGS. 5A and 5B are a plan view showing the configuration of a chip-on-board (COB) & chip-on-heat-sink (COH) type light emitting diode package and a flowchart showing a process of manufacturing the same in accordance with an exemplary embodiment of the present invention.

First, as shown in FIG. 5A, a chip-on-board (COB) & chip-on-heat-sink (COH) type light emitting diode package in accordance with an exemplary embodiment of the present invention uses a PCB 40 such as an FR4 PCB (COB type PCB) or a metal PCB (COH type PCB) comprising an insulating layer 31 of 50 to 100 μm in thickness and a copper (Cu) layer 32 of ½ ounce (about 17 μm) or 1 ounce (about 34 μm) in thickness.

Here, it is necessary to form a silver (Ag) layer for wire bonding as a plating layer for LED packaging by COB & COH. However, it is impossible to directly plate the Cu layer with silver, and thus a nickel (Ni) layer is formed on the Cu layer by plating as a buffer layer for Ag plating.

Wiring pattern-forming material layers are formed by the above-described process, dams having a predetermined height to prevent a fluorescent material or silicone from spreading during application are formed, and then LED chips are mounted thereon.

That is, first, second, and third wiring pattern-forming material layers are formed of materials having excellent electrical conductivity such as Cu, Ni and Ag on the PCB or metal PCB, the dams each having a predetermined height to prevent a fluorescent material or silicone from spreading during application are formed around chip mounting areas, a light reabsorption prevention dam is formed between the chip mounting areas where the LED chips are mounted, and then the LED are mounted in the chip mounting areas.

First, according to a chip-on-board (COB) & chip-on-heat-sink (COH) process, a PCB is manufactured by a typically used PCB manufacturing process (S501).

That is, a typically used PCB or metal PCB such as an FR4 PCB (COB type PCB) or metal PCB (COH type PCB; comprising an insulating layer of 50 to 100 μm in thickness and a copper (Cu) layer of ½ ounce (about 17 μm) or 1 ounce (about 34 μm) in thickness is used to prepare a COB & COH type PCB by a PCB manufacturing process such as exposing, etching etc.

Here, it is necessary to form a silver (Ag) layer for wire bonding as a plating layer for LED packaging by COB & COH. However, it is impossible to directly plate the Cu layer with silver, and thus a nickel (Ni) layer is formed on the Cu layer by plating as a buffer layer for Ag plating.

That is, the Ni is used as the second wiring pattern-forming material layer to allow the Ag used as the third wiring pattern-forming material layer to be plated directly on the Cu layer used as the first wiring pattern-forming material layer.

The Ag used as the third wiring pattern-forming material layer is to improve the reflectance and facilitate a wire bonding process.

The Cu layer used as the first wiring pattern-forming material layer may be selectively formed in a desired area by forming a mask layer and sputtering the mask layer.

Subsequently, the dams each having a predetermined height to prevent a fluorescent material or silicone from spreading during application are formed around the chip mounting areas, and the light reabsorption prevention dam is formed between the chip mounting areas where the LED chips are mounted.

The process of forming the dams and the light reabsorption prevention dam may be achieved by repeatedly printing white ink several times (S502), by applying and curing a dam-forming material using a dispenser (S503), or by forming a reflective structure (S504). These dam forming processes may be selected to be suitable for the characteristics of products.

Here, the dams are formed on the wiring pattern-forming material layers around the chip mounting area of the PCB or metal PCB, and the light reabsorption prevention dam is formed on the wiring pattern-forming material layers between the chip mounting areas where the LED chips are mounted.

Then, the LED chips are bonded to the chip mounting areas between which the light reabsorption prevention dam is formed, and a wire bonding process for electrically connecting electrodes of the LED chips to bonding pads is performed (S505).

Next, the structure and manufacturing process of a chip-on-metal (COM) type light emitting diode package in accordance with another exemplary embodiment of the present invention will now be described.

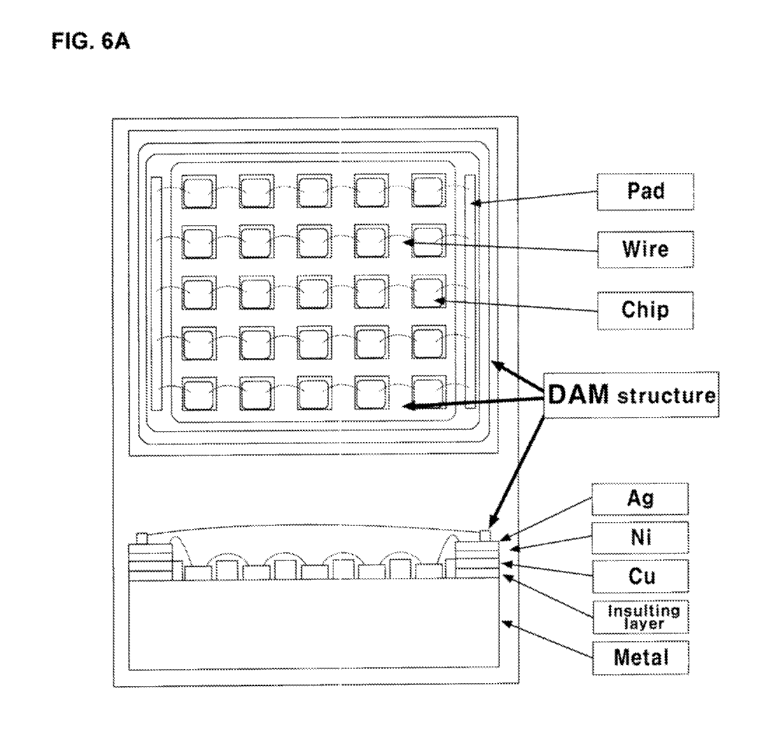

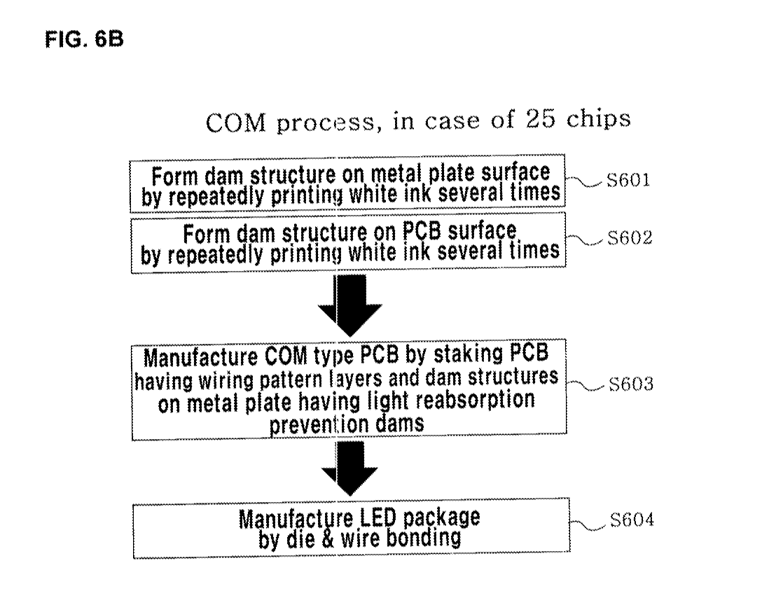

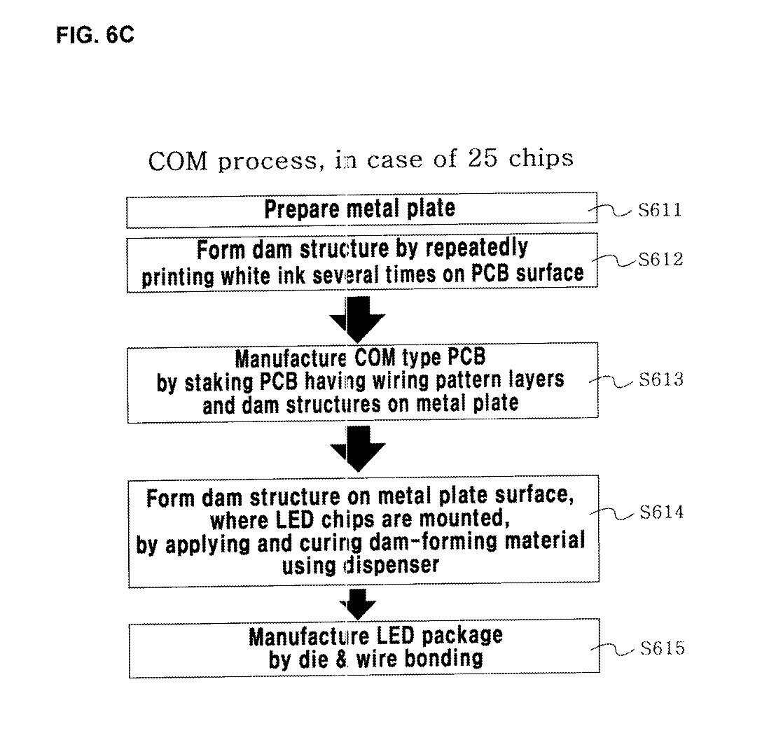

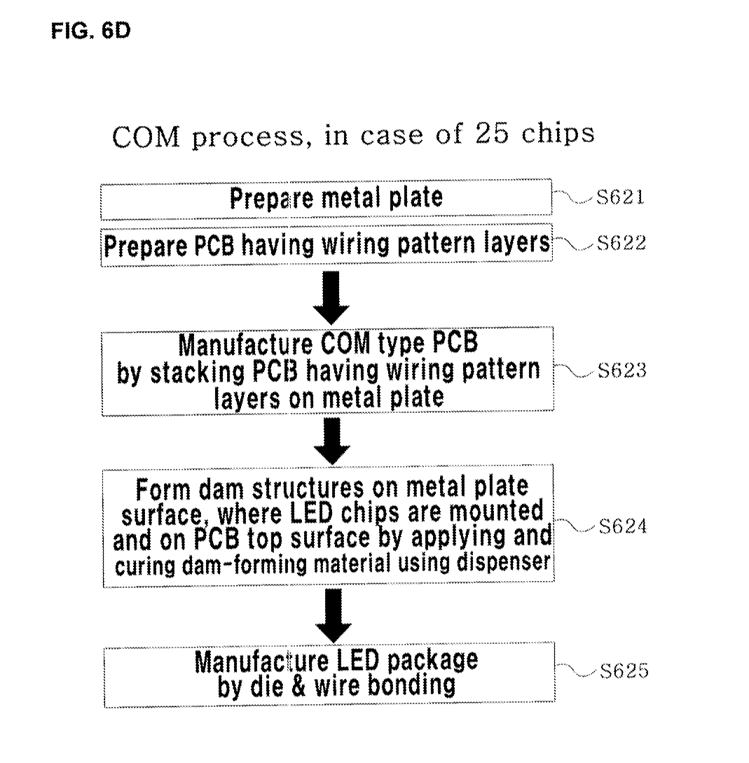

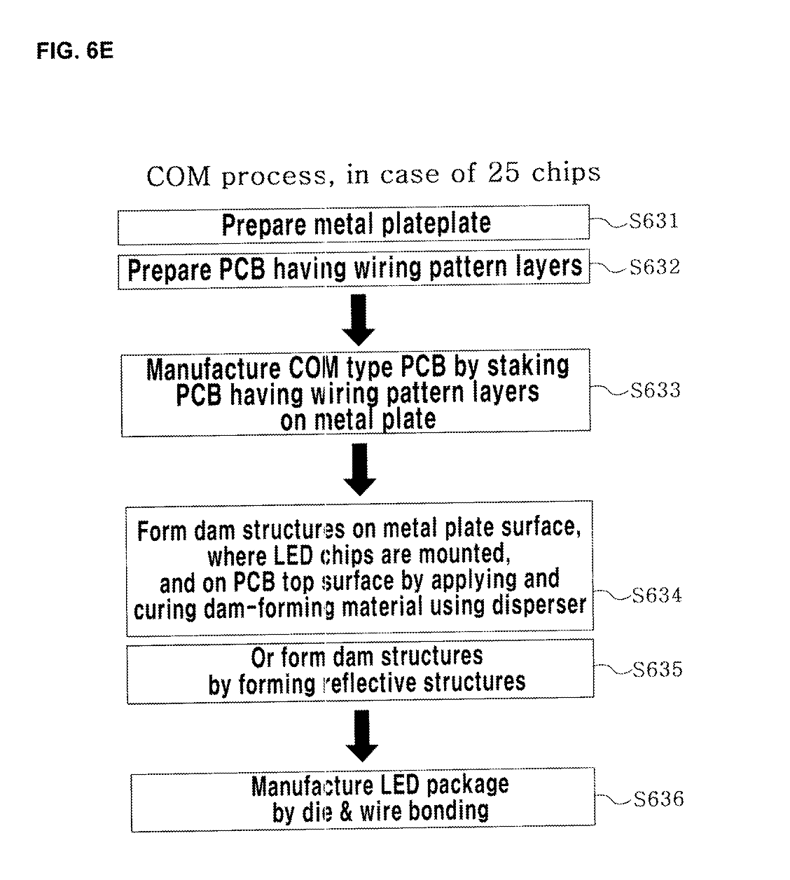

FIGS. 6A and 6E are a plan view showing the configuration of a chip-on-metal (COM) type light emitting diode package and flowcharts showing processes of manufacturing the same in accordance with other exemplary embodiments of the present invention.

As shown in FIG. 6A, according to a chip-on-metal (COM) type light emitting diode package in accordance with another exemplary embodiment of the present invention, a metal plate (or surface-treated metal plate) and a PCB formed by a PCB manufacturing process and a Ni and Ag plating process are bonded by hot press, thus manufacturing a COM type metal PCB.

Wiring layers of the COM type metal PCB formed by the above-described process are formed by forming first, second, and third wiring pattern-forming material layers using materials having excellent electrical conductivity such as Cu, Ni and Ag, dams each having a predetermined height to prevent a fluorescent material or silicone from spreading during application are formed around chip mounting areas, light reabsorption prevention dams are formed between the chip mounting areas where LED chips are mounted, and then LED chips are mounted on the surface of the metal plate.

As shown in FIG. 6B, according to a chip-on-metal (COM) process in accordance with still another exemplary embodiment of the present invention, light reabsorption prevention dams are first formed on the surface of the metal plate by repeatedly printing white ink several times (S601).

Then, wiring pattern layers are formed on a PCB by forming first, second, and third wiring pattern-forming material layers using materials having excellent electrical conductivity such as Cu, Ni and Ag and patterning the wiring pattern-forming material layers, and dams each having a predetermined height to prevent a fluorescent material or silicone from spreading during application are formed around chip mounting areas by repeatedly printing white ink several times on the surface of the PCB (S602).

Subsequently, the PCB having the wiring pattern layers and the dams is stacked on the metal plate having the light reabsorption prevention dams, thus forming a COM type PCB (S603).

Then, the LED chips are bonded to the chip mounting areas between which the light reabsorption prevention dams are formed, and a wire bonding process for electrically connecting electrodes of the LED chips to bonding pads is performed (S604).

As shown in FIG. 6C, according to a chip-on-metal (COM) (COH) process in accordance with yet another exemplary embodiment of the present invention, a metal plate is first prepared (S611), wiring pattern layers are formed on a PCB by forming first, second, and third wiring pattern-forming material layers using materials having excellent electrical conductivity such as Cu, Ni and Ag and patterning the wiring pattern-forming material layers, and dams each having a predetermined height to prevent a fluorescent material or silicone from spreading during application are formed around chip mounting areas by repeatedly printing white ink several times on the surface of the PCB (S612).

Subsequently, the PCB having the wiring pattern layers and the dams is stacked on the metal plate, thus forming a COM type PCB (S613).

Then, light reabsorption prevention dams are formed on the surface of the metal plate where LED chips are mounted by applying and curing a dam-forming material using a dispenser (S614).

Then, the LED chips are bonded to the chip mounting areas between which the light reabsorption prevention dams are formed, and a wire bonding process for electrically connecting electrodes of the LED chips to bonding pads is performed (S615).

As shown in FIG. 6D, according to a chip-on-metal (COM) (COH) process in accordance with still yet another exemplary embodiment of the present invention, a metal plate is first prepared (S621), and wiring pattern layers are formed on a PCB by forming first, second, and third wiring pattern-forming material layers using materials having excellent electrical conductivity such as Cu, Ni and Ag and patterning the wiring pattern-forming material layers (S622).

Subsequently, the PCB having the wiring pattern layers is stacked on the metal plate, thus forming a COM type PCB (S623).

Then, dams each having a predetermined height to prevent a fluorescent material or silicone from spreading curing application are formed around chip mounting areas on the top surface of the PCB and light reabsorption prevention dams are formed on the surface of the metal plate by applying and curing a dam-forming material using a dispenser on the surface of the metal plate where the LED chips are mounted and the top surface of the PCB (S624).

Then, the LED chips are bonded to the chip mounting areas between which the light reabsorption prevention dams are formed, and a wire bonding process for electrically connecting electrodes of the LED chips to bonding pads is performed (S625).

As shown in FIG. 6E, according to a chip-on-metal (COM) (COH) process in accordance with a further exemplary embodiment of the present invention, a metal plate is first prepared (S631), and wiring pattern layers are formed on a PCB by forming first, second, and third wiring pattern-forming material layers using materials having excellent electrical conductivity such as Cu, Ni and Ag and patterning the wiring pattern-forming material layers (S632).

Subsequently, the PCB having the wiring pattern layers is stacked on the metal plate, thus forming a COM type PCB (S633).

Then, dams each having a predetermined height to prevent a fluorescent material or silicone from spreading during application are formed around chip mounting areas on the top surface of the PCB, and light reabsorption prevention dams are formed on the surface of the metal plate by applying and curing a dam-forming material using a dispenser on the surface of the metal plate where the LED chips are mounted and the top surface of the PCB (S634).

Here, the process of forming the dams and the light reabsorption prevention dams may be achieved by directly forming a reflective structure in the dam-forming area according to the progress of the process other than the use of the dispenser (S635).

Then, the LED chips are bonded to the chip mounting areas between which the light reabsorption prevention dams are formed, and a wire bonding process for electrically connecting electrodes of the LED chips to bonding pads is performed (S636).

As such, the PCB having the individual reflective structure and the method for manufacturing an LED package using the same according to the present invention can prevent the reabsorption of light between the LED chips by providing the individual reflective structure between the LED chips when the LED package is configured using two or more LED chips.

Therefore, it is possible to improve light efficiency by preventing the reabsorption of light between the LED chips and improve the efficiency of the process by applying the present invention to both the COB & COH type PCB and the COM type PCB.

As described above, the PCB having the individual reflective structure and the method for manufacturing an LED package using the same according to the present invention have the following effects.

First, it is possible to prevent reabsorption of light between the LED chips by providing the individual reflective structure between the LED chips when the LED package is configured using two or more LED chips.

Second, it is possible to prevent reabsorption of light between the LED chips by providing the dam structure for individual reflection by printing, thus improving light efficiency.

Third, the process of providing the structure for individual reflection between the LED chips can be achieved by printing using white ink, by applying and curing a dam-forming material, or by directly forming a reflective structure, which is suitable for the package structure and process, thus improving the efficiency of the process.

Fourth, it is possible to selectively apply the process of forming the individual reflective structure to the process of processing and manufacturing a PCB circuit by the chip-on-board (COB), chip-on-heat-sink (COH), or chip-on-metal (COM) process, thus facilitating the process.

While the invention has been shown and described with reference to certain preferred embodiments thereof, it will be understood by those skilled in the art that various changes in form and details may be made therein without departing from the spirit and scope of the invention as defined by the appended claims.

Therefore, the scope of the invention is defined not by the detailed description of the invention but by the appended claims, and all differences within the scope will be construed as being included in the present invention.

What is claimed is:

1. A printed circuit board (PCB) having an individual reflective structure, the PCB comprising:
a PCB;
a wiring pattern-forming material layer formed on the PCB with an insulating layer interposed therebetween;
dams formed on the wiring pattern-forming layer around chip mounting areas of the PCB; and
a light reabsorption prevention dam formed on the wiring pattern-forming material layer between the chip mounting areas where light emitting diode (LED) chips are mounted.

2. The PCB of claim 1, wherein the PCB has a structure in which two or more LED chips are mounted by a chip-on-board (COB) or chip-on-heat-sink (COH) process.

3. A PCB having an individual reflective structure, the PCB comprising:
a metal plate;
a wiring pattern stacked on the metal plate;
dams formed on the wiring pattern around chip mounting areas of the metal plate; and
light reabsorption prevention dams formed on the surface of the metal plate between the chip mounting areas where LED chips are mounted.

4. The PCB of claim 3, wherein the metal plate has reflection and gloss properties improved by surface treatment.

5. The PCB of claim 4, wherein the surface treatment of the metal plate improves the reflection and gloss properties by performing any one of coating, deposition, lamination, and sputtering on an aluminum plate.

6. The PCB of claim 3, wherein the PCB has a structure in which a plurality of LED chips are mounted in a single LED package by a Chip-on-Metal (COM) process.

7. The PCB of claim 1, wherein the light reabsorption prevention dam is formed by repeatedly printing white ink, by applying and curing a dam-forming material, or by directly forming a reflective structure.

8. The PCB of claim 3, wherein the light reabsorption prevention dam is formed by repeatedly printing white ink, by applying and curing a dam-forming material, or by directly forming a reflective structure.

9. A method for manufacturing an LED package using a PCB having an individual reflective structure, the method comprising:
forming a wiring pattern-forming material layer on a metal plate with an insulating layer interposed therebetween;
forming dams on the wiring pattern-forming layer around chip mounting areas of the metal plate and a light reabsorption prevention dam on the wiring pattern-forming material layer between the chip mounting areas where LED chips are mounted, respectively; and
bonding the LED chips to the chip mounting areas between which the light reabsorption prevention dam is formed and performing a wire bonding process for electrically connecting electrodes of the LED chips to bonding pads.

10. The method of claim 9, wherein the forming of the dams and the light reabsorption prevention dam is performed by repeatedly printing white ink, by applying and curing a dam-forming material using a dispenser, or by directly forming a reflective structure.

11. A method for manufacturing an LED package using a PCB having an individual reflective structure, the method comprising:
forming light reabsorption prevention dams on a metal plate by repeatedly printing white ink on the surface of a metal plate between chip bonding areas where LED chips are mounted;
forming a wiring pattern layer on a PCB and forming dams on the wiring pattern layer around the chip bonding areas by repeatedly printing white ink on the surface of the PCB;
stacking the PCB having the wiring pattern layer and the dams on the metal plate having the light reabsorption prevention dams; and
bonding the LED chips to the chip mounting areas between which the light reabsorption prevention dams are formed and performing a wire bonding process for electrically connecting electrodes of the LED chips to bonding pads.

12. A method for manufacturing an LED package using a PCB having an individual reflective structure, the method comprising:
forming a wiring pattern layer on a PCB and forming dams on the wiring pattern layer around chip bonding areas by repeatedly printing white ink on the surface of the PCB;
stacking the PCB having the wiring pattern layer and the dams on a metal plate;
forming light reabsorption prevention dams on the metal plate where LED chips are mounted by applying and curing a dam-forming material using a dispenser on the surface of the metal plate; and
bonding the LED chips to the chip mounting areas between which the light reabsorption prevention dams are formed and performing a wire bonding process for electrically connecting electrodes of the LED chips to bonding pads.

13. A method for manufacturing an LED package using a PCB having an individual reflective structure, the method comprising:
forming a wiring pattern layer on a PCB and stacking the PCB having the wiring pattern layer on a metal plate;
forming dams on the wiring pattern layer around chip mounting areas and light reabsorption prevention dams on the surface of the metal plate by applying and curing a dam-forming material using a dispenser on the surface of the metal plate where LED chips are mounted and on the top surface of the PCB; and
bonding the LED chips to the chip mounting areas between which the light reabsorption prevention dams are formed and performing a wire bonding process for electrically connecting electrodes of the LED chips to bonding pads.

14. The method of claim 13, wherein the forming of the dams on the wiring pattern layer and the light reabsorption prevention dams on the surface of the metal plate is performed by directly forming a reflective structure in the dam-forming area, respectively.
